(19) United States
(12) Patent Application Publication
(10) Pub. No.: US 2026/0304975 A1
(43) Pub. Date: Oct. 1, 2026

(54) IMAGE SENSING DEVICE

(71) Applicant: SK hynix Inc., Icheon-si (KR)

(72) Inventor: Hyun Soo LIM, Icheon-si (KR)

(21) Appl. No.: 19/331,971

(22) Filed: Sep. 17, 2025

(30) Foreign Application Priority Data
Apr. 1, 2025 (KR) 10-2025-0041942

(51) Int. Cl. H10F 39/00

(52) U.S. Cl. CPC H10F 39/80373

(57) ABSTRACT

An image sensing device including a floating diffusion region is disclosed. The image sensing device includes a semiconductor substrate; a photoelectric conversion element disposed in the semiconductor substrate, and configured to generate photocharges in response to incident light; a body region formed in the semiconductor substrate and configured to surround the photoelectric conversion element; and a floating diffusion region formed in the semiconductor substrate adjacent to the photoelectric conversion element to receive and store the photocharges generated by the photoelectric conversion element, the floating diffusion region structured to include a silicide region that is recessed into the semiconductor substrate and includes a side surface and a bottom surface that are in contact with the body region.

### CROSS-REFERENCE TO RELATED APPLICATION

This patent document claims the priority and benefits of Korean patent application No. 10-2025-0041942, filed on Apr. 1, 2025, the disclosure of which is incorporated herein by reference in its entirety as part of the disclosure of this patent document.

### TECHNICAL FIELD

The technology and implementations disclosed in this patent document generally relate to an image sensing device, and more particularly to an image sensing device including a floating diffusion region.

### BACKGROUND

An image sensing device is a device for capturing optical images by converting light into electrical signals using a photosensitive semiconductor material which reacts to light. With the development of automotive, medical, computer and communication industries, the demand for high-performance image sensing devices is increasing in various fields such as smartphones, digital cameras, game machines, IoT (Internet of Things), robots, security cameras and medical micro cameras.

The image sensing device may be roughly divided into CCD (Charge Coupled Device) image sensing devices and CMOS (Complementary Metal Oxide Semiconductor) image sensing devices. The CCD image sensing devices offer a better image quality, but they tend to consume more power and are larger as compared to the CMOS image sensing devices. The CMOS image sensing devices are smaller in size and consume less power than the CCD image sensing devices. Furthermore, CMOS sensors are fabricated using the CMOS fabrication technology, and thus photosensitive elements and other signal processing circuitry can be integrated into a single chip, enabling the production of miniaturized image sensing devices at a lower cost. For these reasons, CMOS image sensing devices are being developed for many applications including mobile devices.

### SUMMARY

Various embodiments of the present disclosure relate to an image sensing device that prevents occurrence of a gate induced drain leakage (GIDL) phenomenon in which a conversion gain is reduced because unnecessary capacitance occurs as a transfer transistor and a floating diffusion region overlap each other.

In accordance with an embodiment of the present disclosure, an image sensing device may include: a semiconductor substrate; a photoelectric conversion element disposed in the semiconductor substrate, and configured to generate photocharges in response to incident light; a body region formed in the semiconductor substrate and configured to surround the photoelectric conversion element; and a floating diffusion region formed in the semiconductor substrate adjacent to the photoelectric conversion element to receive and store the photocharges generated by the photoelectric conversion element, the floating diffusion region structured to include a silicide region that is recessed into the semiconductor substrate and includes a side surface and a bottom surface that are in contact with the body region.

In some implementations, the image sensing device may further include: a transfer gate disposed on a surface of the semiconductor substrate, and configured to overlap the photoelectric conversion element in a vertical direction perpendicular to the surface of the semiconductor substrate, wherein a gate electrode layer of the transfer gate is spaced apart from the floating diffusion region in the vertical direction.

In some implementations, at least a portion of an upper portion of the gate electrode layer may include a silicide.

In some implementations, the photoelectric conversion element may include: an upper photoelectric conversion region configured to have a first width; and a lower photoelectric conversion region formed at a location below the upper photoelectric conversion region and configured to have a second width greater than the first width.

In some implementations, the upper photoelectric conversion region may be spaced apart from the floating diffusion region; and the lower photoelectric conversion region may overlap the floating diffusion region.

In some implementations, the photoelectric conversion element may include impurities of a first conductivity type; and the body region may include impurities of a second conductivity type opposite to the first conductivity type.

In some implementations, the silicide region may be disposed along a top surface, a side surface, and a bottom surface of the floating diffusion region.

In some implementations, the silicide region may extend into the floating diffusion region.

In some implementations, the silicide region may gap-fill an interior of the floating diffusion region.

In accordance with another embodiment of the present disclosure, an image sensing device may include: first to fourth photoelectric conversion elements disposed in a semiconductor substrate to be spaced apart from each other, each of the first to fourth photoelectric conversion elements configured to generate photocharges in response to incident light; a body region surrounding each of the first to fourth photoelectric conversion elements; and a floating diffusion region including a silicide region recessed into the semiconductor substrate and configured to store photocharges generated by the first photoelectric conversion element, wherein the silicide region is arranged along a top surface, a side surface, and a bottom surface of the floating diffusion region.

In some implementations, the image sensing device may further include: a transfer gate configured to move the photocharges generated by the first photoelectric conversion element to the floating diffusion region, wherein a gate electrode layer of the transfer gate is spaced apart from the floating diffusion region in a vertical direction perpendicular to one surface of the semiconductor substrate.

In some implementations, at least a portion of an upper portion of the gate electrode layer may include a second silicide.

In some implementations, the first photoelectric conversion element and the second photoelectric conversion element may be spaced apart from each other in a first direction. The first photoelectric conversion element and the third photoelectric conversion element may be spaced apart from each other in a second direction. The floating diffusion region may be arranged between the second photoelectric conversion element and the third photoelectric conversion element.

In some implementations, the floating diffusion region may extend between the first and second photoelectric conversion elements in the second direction; and the floating diffusion region may extend between the first and third photoelectric conversion elements in the first direction.

In some implementations, the silicide region may extend into the floating diffusion region.

In some implementations, the silicide region may gap-fill an interior of the floating diffusion region.

In some implementations, each of the first to fourth photoelectric conversion elements may include impurities of a first conductivity type; and the body region may include impurities of a second conductivity type opposite to the first conductivity type.

In some implementations, the floating diffusion region is shared by the first to fourth photoelectric conversion elements to receive photocharges each of the first to fourth photoelectric conversion elements.

It is to be understood that both the foregoing general description and the following detailed description of the present disclosure are illustrative and explanatory and are intended to provide further explanation of the present disclosure as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a block diagram illustrating an example of an image sensing device based on some embodiments of the present disclosure.

FIG. 2 is a plan view illustrating an example of a pixel array of the image sensing device shown in FIG. 1 based on some embodiments of the present disclosure.

FIG. 3A is a circuit diagram illustrating an example of a pixel included in the pixel array shown in FIG. 2 based on some embodiments of the present disclosure.

FIG. 3B is a circuit diagram illustrating an example of first to fourth pixels included in the pixel array shown in FIG. 2 based on some embodiments of the present disclosure.

FIG. 4A is a cross-sectional view illustrating an example of the pixel array taken along the line A-A′ shown in FIG. 2 according to a first embodiment of the present disclosure.

FIG. 4B is a cross-sectional view illustrating an example of the pixel array taken along the line A-A′ shown in FIG. 2 according to a second embodiment of the present disclosure.

FIG. 5A is a plan view illustrating an example of the first to fourth pixels shown in FIG. 2 according to the first embodiment of the present disclosure.

FIG. 5B is a plan view illustrating an example of the first to fourth pixels shown in FIG. 2 according to the second embodiment of the present disclosure.

### DETAILED DESCRIPTION

This patent document provides implementations and examples of an image sensing device including a floating diffusion region that may be used in configurations to substantially address one or more technical or engineering issues and to mitigate limitations or disadvantages encountered in some other image sensing devices. Some implementations of the present disclosure relate to an image sensing device that prevents occurrence of a gate induced drain leakage (GIDL) phenomenon in which a conversion gain is reduced because unnecessary capacitance occurs as a transfer transistor and a floating diffusion region overlap each other. In recognition of the issues above, the present disclosure may provide an image sensing device that prevents a reduction in conversion gain by minimizing the amount of unnecessary capacitance because a floating diffusion region and a transfer transistor does not overlap each other, so that occurrence of gate induced drain leakage (GIDL) can be prevented.

Reference will now be made in detail to the embodiments of the present disclosure, examples of which are illustrated in the accompanying drawings. Wherever possible, the same reference numbers will be used throughout the drawings to refer to the same or like parts. While the present disclosure is susceptible to various modifications and alternative forms, specific embodiments thereof are shown by way of example in the drawings. However, the present disclosure should not be construed as being limited to the embodiments set forth herein.

Hereinafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of effects capable of being directly or indirectly recognized through the present disclosure.

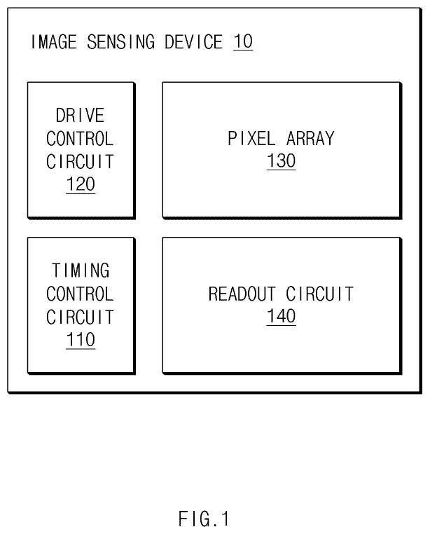

FIG. 1 is a schematic diagram illustrating an example of an image sensing device 10 based on some embodiments of the present disclosure.

Referring to FIG. 1, the image sensing device 10 according to an exemplary embodiment of the present disclosure may include a timing control circuit 110, a drive control circuit 120, a pixel array 130, and a readout circuit 140. The constituent components of the image sensing device 10 illustrated in FIG. 1 are discussed by way of example only, and this patent document encompasses numerous other changes, substitutions, variations, alterations, and modifications. In this patent document, the word “pixel” can be used to indicate an image sensing pixel that is structured to include at least one a photoelectric conversion element (PD) that detects incident light to generate photocharge that is output in form of an electrical signal and an array of such pixels can be used to generate electrical signals carrying images in the incident light. For example, the image sensing device 10 may be a Complementary Metal Oxide Semiconductor (CMOS) image sensor configured to convert incident light into an electrical signal.

The timing control circuit 110 may generate a timing signal to control the operations of the drive control circuit 120 and the readout circuit 140. In some implementations, the timing control circuit 110 may generate a timing signal in response to a request from an external processor (e.g., an image signal processor ISP). In some implementations, the timing control circuit 110 may include a logic control circuit, a phase-locked loop (PLL) circuit, a communication interface circuit, and the like.

The drive control circuit 120 may drive pixels (PXs) of the pixel array 130 in response to a timing signal output from the timing control circuit 110. The drive control circuit 120 may select and control pixels (PXs) included in at least one row line from among a plurality of row lines of the pixel array 130. The drive control circuit 120 may generate a row selection signal to select at least one row from among the plurality of rows. The drive control circuit 120 may sequentially enable a pixel reset signal and a transfer signal for pixels (PXs) corresponding to at least one selected row. Accordingly, an analog reference signal and an image signal generated from each of the pixels (PXs) of the selected row may be sequentially transmitted to the readout circuit 140. The reference signal may be an electrical signal provided to the readout circuit 140 when a floating diffusion region (FD) of each pixel is reset to a power-supply voltage (VDD). The image signal may be an electrical signal provided to the readout circuit 140 when photocharges generated by each pixel are accumulated in the floating diffusion region (FD). The reference signal indicating unique pixel noise of each pixel, and the image signal indicating the intensity of incident light may be collectively referred to as a pixel signal as necessary.

The pixel array 130 may include a plurality of pixels (PXs) arranged in rows and columns. In one example, the plurality of pixels (PXs) can be arranged in a two-dimensional (2D) pixel array including rows and columns. In another example, the plurality of pixels (PXs) can be arranged in a three-dimensional (3D) pixel array. The plurality of pixels (PXs) may convert an optical signal into an electrical signal on a pixel basis or a pixel group basis, and may output a pixel signal. Here, the pixels in a pixel group of the pixel array 130 may share at least certain internal circuitry. The pixel array 130 may receive driving signals including a row selection signal, a pixel reset signal, a transfer signal, etc. from the drive control circuit 120. Upon receiving the driving signals, corresponding imaging pixels in the pixel array 130 may be activated to perform the operations corresponding to the row selection signal, the pixel reset signal, and the transfer signal.

The readout circuit 140 may detect a pixel signal output from the pixel array 130 under the control of the timing control circuit 110, and may output the detected pixel signal as image data. The image data may be digital data generated by performing an analog-to-digital conversion process on an analog pixel signal. To this end, the readout circuit 140 may include a correlated double sampler (CDS) for performing correlated double sampling on pixel signals output from the pixel array 130. In addition, the readout circuit 140 may include an analog-to-digital converter (ADC) for converting signals output from the correlated double sampler (CDS) into digital signals to generate pixel data. In addition, the readout circuit 140 may include a buffer circuit for temporarily storing pixel data output from the analog-to-digital converter (ADC) and outputting the stored pixel data to the outside under the control of the timing control circuit 110. The correlated double sampler (CDS) may remove the undesired offset value of pixels by comparing pixel output voltages obtained before and after photocharges generated by photosensing pixels in response to incident light are accumulated in the floating diffusion region (FD) so that only pixel output voltages based on the incident light can be measured. The readout circuit 140 may sequentially sample and hold voltage levels of the reference signal and the image signal, which are provided to each of a plurality of column lines from the pixel array 130. That is, the readout circuit 140 may sample and hold the voltage levels of the reference signal and the image signal which correspond to each of the columns of the pixel array 130. The readout circuit 140 may convert a correlated double sampler (CDS) signal, which is an analog signal for each column, into a digital signal, and may output the digital signal for each column. The readout circuit 140 may temporarily hold image data for each column, and may output the image data to, for example, an image processing device (not shown).

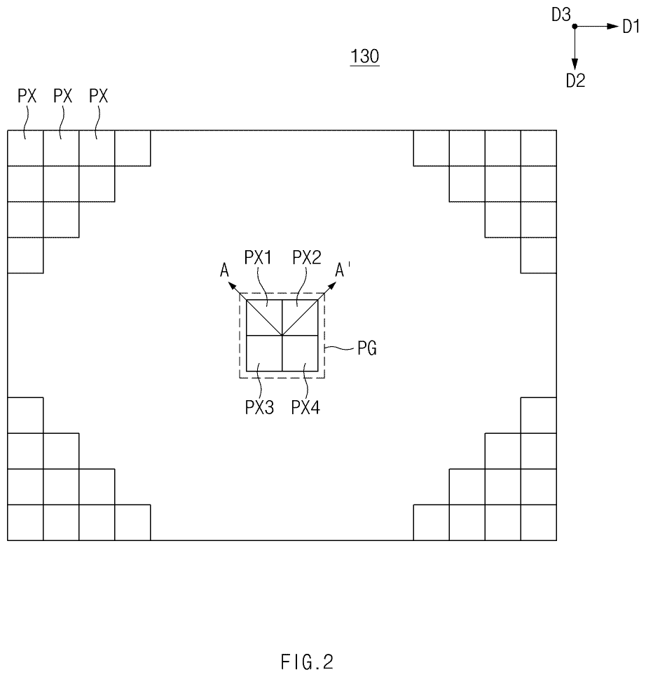

FIG. 2 is a plan view illustrating an example of the pixel array 130 of the image sensing device 10 shown in FIG. 1 based on some embodiments of the present disclosure.

Referring to FIGS. 1 and 2, the pixel array 130 may include, for example, a structure in which a plurality of pixels (PXs) is arranged in a two-dimensional (2D) matrix including rows and columns. The pixel array 130 may include M pixels (PXs) arranged in a horizontal direction (row direction) (where ‘M’ is an integer greater than or equal to 2). The pixel array 130 may include N pixels (PXs) arranged in a vertical direction (where ‘N’ is an integer greater than or equal to 2).

The pixel array 130 may include, as an example of the plurality of pixels (PXs), first to fourth pixels (PX1~PX4). The first to fourth pixels (PX1~PX4) may be arranged in a (2×2) matrix structure including two rows and two columns.

Each of the first to fourth pixels (PX1~PX4) may include one or more photoelectric conversion elements. Each of the first to fourth pixels (PX1~PX4) may include a transfer transistor.

In one embodiment, each of the first to fourth pixels (PX1~PX4) may include one floating diffusion region. In another embodiment, the first to fourth pixels (PX1~PX4) may share one floating diffusion region which receives and stores photocharge generated by the first to fourth pixels (PX1~PX4).

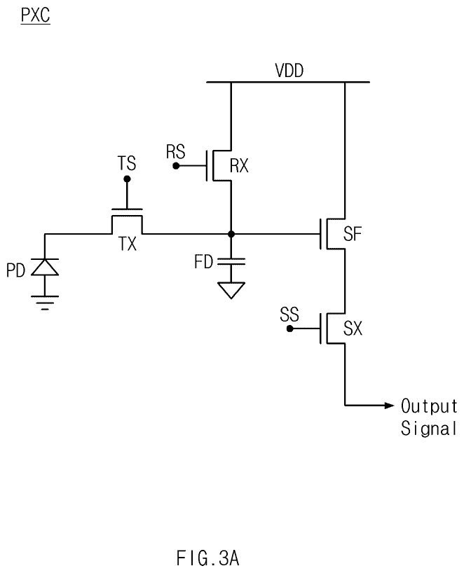

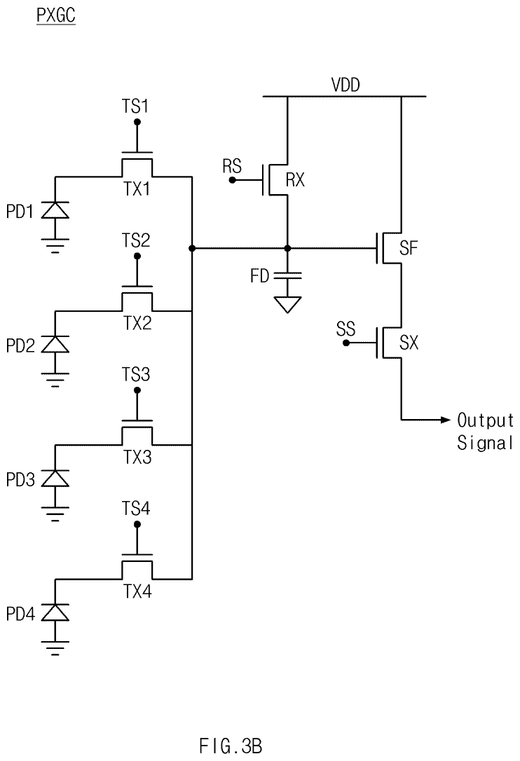

A more detailed description of the pixel including the floating diffusion region will be given with reference to FIG. 3A and below.

FIG. 3A is a circuit diagram illustrating an example of the pixel (PX) included in the pixel array 130 shown in FIG. 2 based on some embodiments of the present disclosure.

FIGS. 2 and 3A are exemplarily circuit diagrams of a unit pixel circuit (PXC) for modeling the pixel (PX) for use in the embodiment in which each pixel (PX) includes one floating diffusion region.

The unit pixel circuit (PXC) may include a photoelectric conversion element (PD), a transfer transistor (TX), a floating diffusion region (FD), a reset transistor (RX), a source follower transistor (SF), and a selection transistor (SX).

The photoelectric conversion element (PD) may generate photocharges in response to incident light. Examples of the photoelectric conversion element (PD) may include, e.g., a photodiode, a photo transistor, a photo gate, or other photosensitive circuitry capable of converting light into a pixel signal (e.g., a charge, a voltage or a current).

Each of the transfer transistors (TXs) may receive a transfer signal (TS) through a gate terminal thereof. When the transfer signal (TS) is at a high level, the transfer transistor (TX) may be in an ON state. When the transfer signal (TS) is at a low level, the transfer transistor (TX) may be in an OFF state.

When the transfer transistor (TX) is turned on (i.e., ON state), the transfer transistor (TX) may move photocharges generated by a photoelectric conversion element (PD) to a floating diffusion region (FD). When the transfer transistor (TX) is turned off (i.e., OFF state), the transfer transistor (TX) may prevent photocharges generated by the photoelectric conversion element (PD) from moving into the floating diffusion region (FD).

The floating diffusion region (FD) may store photocharges generated by the photoelectric conversion element (PD). The intensity of a pixel signal may vary depending on a potential of photocharges stored in the floating diffusion region (FD).

The reset transistor (RX) may receive a pixel reset signal (RS) through a gate terminal thereof. When the pixel reset signal (RS) is at a high level, the reset transistor (RX) may be turned on (i.e., ON state). When the pixel reset signal (RS) is at a low level, the reset transistor (RX) may be turned off (i.e., OFF state).

When the reset transistor (RX) is turned on (i.e., ON state), the reset transistor (RX) may reset a voltage of the floating diffusion region (FD) to a power-supply voltage (VDD). When the reset transistor (RX) is turned off (i.e., OFF state), the reset transistor (RX) may prevent the floating diffusion region (FD) from being reset.

The source follower transistor (SF) may receive a voltage of the floating diffusion region (FD) through a gate terminal thereof. The source follower transistor (SF) may amplify an electrical signal corresponding to the voltage of the floating diffusion region (FD) and transmit the amplified electrical signal to the selection transistor (SF). The source follower transistor (SF) may be connected to the power-supply voltage (VDD) through a drain terminal thereof.

The selection transistor (SX) may receive a row selection signal (SS) through a gate terminal thereof. When the row selection signal (SS) is at a high level, the selection transistor (SX) may be turned on (i.e., ON state). When the row selection signal (SS) is at a low level, the selection transistor (SX) may be turned off (i.e., OFF state).

When the selection transistor (SX) is turned on (i.e., ON state), the selection transistor (SX) may output the amplified electrical signal output from the source follower transistor (SF), for example, to the readout circuit 140. When the selection transistor (SX) is turned off (i.e., OFF state), the selection transistor (SX) may prevent the pixel signal (electrical signal) of the corresponding pixel (PX) from being output to the readout circuit 140 (see FIG. 1).

FIG. 3B is a circuit diagram illustrating an example of the first to fourth pixels (PX1~PX4) included in the pixel array 130 shown in FIG. 2 based on some embodiments of the present disclosure.

FIGS. 2 and 3B are exemplarily circuit diagrams of a pixel group circuit (PXGC) for modeling a pixel group (PG) including the first to fourth pixels (PX1~PX4). The pixel group circuit (PXGC) may be a circuit exemplarily modeling the pixel group (PG) for use in the embodiment in which the first to fourth pixels (PX1~PX4) share one floating diffusion region.

The pixel group circuit (PXGC) may include first to fourth photoelectric conversion elements (PD1~PD4), first to fourth transfer transistors (TX1~TX4), a floating diffusion region (FD), a reset transistor (RX), a source follower transistor (SF), and a selection transistor (SX).

The following embodiments will hereinafter be described with a focus on the characteristics that are different from those of FIG. 3A.

Each of the first to fourth photoelectric conversion elements (PD1~PD4) may generate photocharges in response to incident light. The first photoelectric conversion element (PD1) may be included in the first pixel (PX1). The second photoelectric conversion element (PD2) may be included in the second pixel (PX2). The third photoelectric conversion element (PD3) may be included in the third pixel (PX3). The fourth photoelectric conversion element (PD4) may be included in the fourth pixel (PX4).

The first transfer transistor (TX1) may receive a first transfer signal (TS1) through a gate terminal thereof. When the first transfer transistor (TX1) is turned on (i.e., ON state), the first transfer transistor (TX1) may move photocharges generated by the first photoelectric conversion element (PD1) to the floating diffusion region (FD).

The second transfer transistor (TX2) may receive a second transfer signal (TS2) through a gate terminal thereof. When the second transfer transistor (TX2) is turned on (i.e., ON state), the second transfer transistor (TX2) may move photocharges generated by the second photoelectric conversion element (PD2) to the floating diffusion region (FD).

The third transfer transistor (TX3) may receive a third transfer signal (TS3) through a gate terminal thereof. When the third transfer transistor (TX3) is turned on (i.e., ON state), the third transfer transistor (TX3) may move photocharges generated by the third photoelectric conversion element (PD3) to the floating diffusion region (FD).

The fourth transfer transistor (TX4) may receive a fourth transfer signal (TS4) through a gate terminal thereof. When the fourth transfer transistor (TX4) is turned on (i.e., ON state), the fourth transfer transistor (TX4) may move photocharges generated by the fourth photoelectric conversion element (PD4) to the floating diffusion region (FD).

When one of the first to fourth transfer transistors (TX1~TX4) is turned on (i.e., ON state), the floating diffusion region (FD) may store photocharges generated by the photoelectric conversion element connected to the turned-ON transfer transistor.

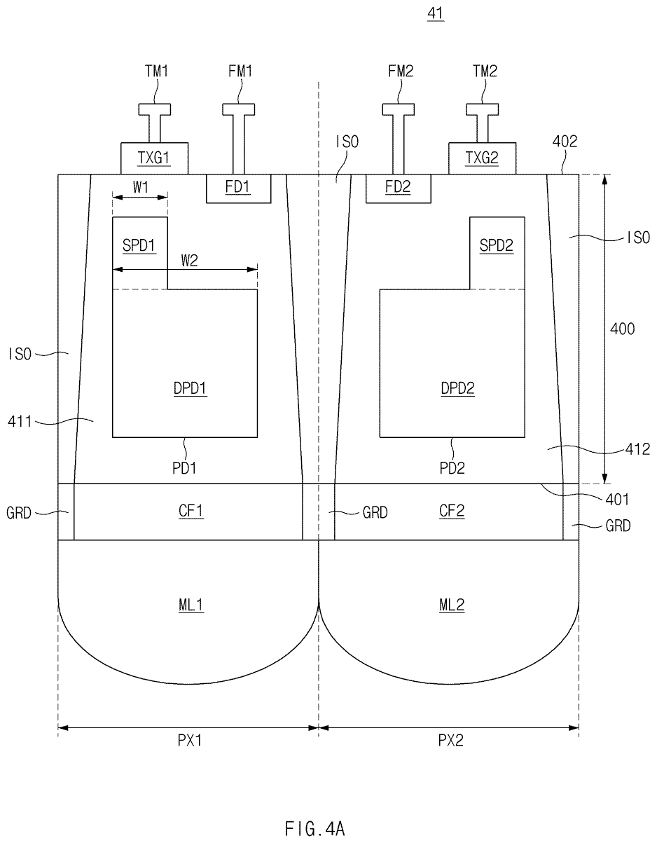

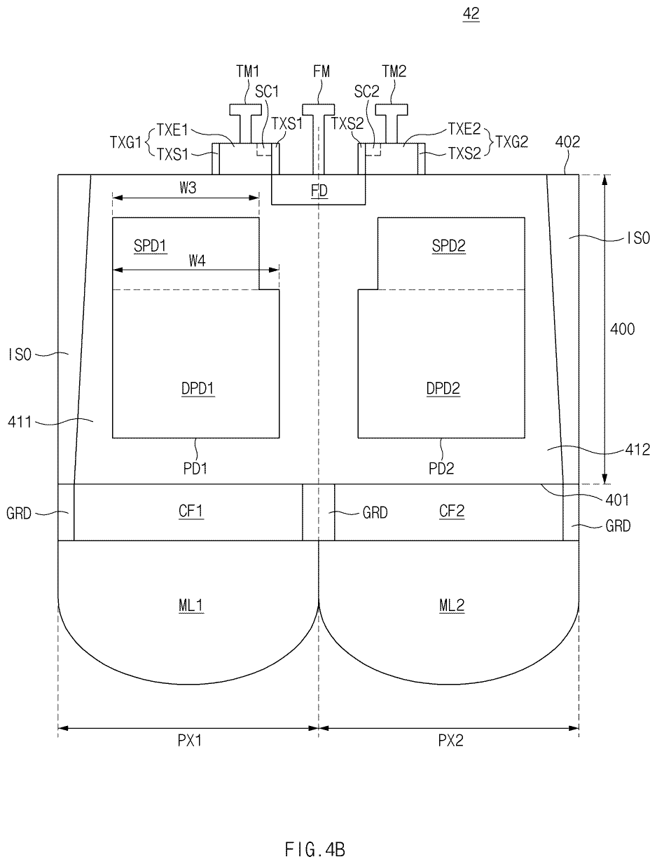

FIG. 4A is a cross-sectional view (41) illustrating an example of the pixel array 130 taken along the line A-A′ shown in FIG. 2 according to a first embodiment of the present disclosure.

Referring to FIGS. 2, 3A, and 4A, a first cross-sectional view 41 according to the first embodiment may be an example in which each of the first to fourth pixels (PX1~PX4) includes one floating diffusion region (FD). According to the first embodiment, the first pixel (PX1) may include a first floating diffusion region (FD1), and the second pixel (PX2) may include a second floating diffusion region (FD2).

The first cross-sectional view 41 may include a first transfer gate (TXG1), a first transfer interconnect line (TM1), a second transfer gate (TXG2), a second transfer interconnect line (TM2), a first floating diffusion interconnect line (FM1), a second floating diffusion interconnect line (FM2), a semiconductor substrate 400, a grid structure (GRD), a first color filter (CF1), a second color filter (CF2), a first microlens (ML1), and a second microlens (ML2).

The first transfer gate (TXG1) may include a first gate electrode layer (TXE1) and a first gate spacer (TXS1). The first transfer gate (TXG1) may have a planar gate structure, but is not limited thereto. For example, the first transfer gate (TXG1) may include a trench gate structure recessed into the semiconductor substrate 400. Hereinafter, an embodiment in which the first transfer gate (TXG1) has a planar gate structure will be exemplarily described with reference to the attached drawings.

The first gate electrode layer (TXE1) may receive a first transfer signal as an input. The first gate electrode layer (TXE1) may be disposed on a front surface 402 of the semiconductor substrate 400. A first gate insulation layer (not shown) may be disposed between the first gate electrode layer (TXE1) and the front surface 402. The first gate insulation layer may be formed to contact the front surface 402 of the semiconductor substrate 400.

The first gate electrode layer (TXE1) may overlap at least a portion of the first photoelectric conversion element (PD1) in a vertical direction perpendicular to the front surface 402. The first gate electrode layer (TXE1) may be spaced apart from the first floating diffusion region (FD1) in the vertical direction, but is not limited thereto.

A first gate spacer (TXS1) may be formed to contact both side surfaces of the first gate electrode layer (TXE1). The first gate spacer (TXS1) may electrically isolate the first gate electrode layer (TXE1) from peripheral structures (e.g., the first floating diffusion interconnect line FM1).

The first gate spacer (TXS1) may overlap at least a portion of the first photoelectric conversion element (PD1) in a vertical direction perpendicular to the front surface 402 of the semiconductor substrate 400. Although FIG. 4A illustrates one embodiment in which the first gate spacer (TXS1) is spaced apart from the first floating diffusion region (FD1) in the vertical direction for convenience of description, other implementations are also possible, and it should be noted that at least a portion of the first gate spacer (TXS1) may also overlap the first floating diffusion region (FD1) in the vertical direction as necessary.

A first transfer interconnect line (TM1) may be formed to contact a first transfer gate (TXG1). The first transfer interconnect line (TM1) may be an interconnect line through which the first transfer signal is transmitted to the first transfer gate (TXG1). The first transfer interconnect line (TM1) may include a conductive material (e.g., a metal material).

A second transfer gate (TXG2) may include a second gate electrode layer (TXE2) and a second gate spacer (TXS2). Although the second transfer gate (TXG2) is formed to have a planar gate structure for convenience of description, other implementations are also possible. For example, the second transfer gate (TXG2) may include a trench gate structure recessed into the semiconductor substrate 400. Hereinafter, an embodiment in which the second transfer gate (TXG2) has a planar gate structure will be exemplarily described with reference to the attached drawings.

A second gate electrode layer (TXE2) may receive a second transfer signal as an input. The second gate electrode layer (TXE2) may be disposed on the front surface 402 of the semiconductor substrate 400. A second gate insulation layer (not shown) may be disposed between the second gate electrode layer (TXE2) and the front surface 402. The second gate insulation layer may be formed to contact the front surface 402 of the semiconductor substrate 400.

The second gate electrode layer (TXE2) may overlap at least a portion of the second photoelectric conversion element (PD2) in a vertical direction perpendicular to the front surface 402 of the semiconductor substrate 400. The second gate electrode layer (TXE2) may be spaced apart from the second floating diffusion region (FD2) in the vertical direction, but other implementations are also possible.

A second gate spacer (TXS2) may be formed to contact with both side surfaces of the second gate electrode layer (TXE2). The second gate spacer (TXS2) may electrically isolate the second gate electrode layer (TXE2) from peripheral structures (e.g., the second floating diffusion interconnect line FM2).

The second gate spacer (TXS2) may overlap at least a portion of the second photoelectric conversion element (PD2) in a vertical direction perpendicular to the front surface 402 of the semiconductor substrate 400.

Although FIG. 4A illustrates one embodiment in which the second gate spacer (TXS2) is spaced apart from the second floating diffusion region (FD2) in the vertical direction for convenience of description, other implementations are also possible. It should be noted that at least a portion of the second gate spacer (TXS2) may also overlap the second floating diffusion region (FD2) in the vertical direction.

A second transfer interconnect line (TM2) may contact the second transfer gate (TXG2). The second transfer interconnect line (TM2) may be an interconnect line through which the second transfer signal is transmitted to the second transfer gate (TXG2). The second transfer interconnect line (TM2) may include a conductive material (e.g., a metal material).

A first floating diffusion interconnect line (FM1) may contact the first floating diffusion region (FD1). The first floating diffusion interconnect line (FM1) may connect (not shown) the first floating diffusion region (FD1) to a gate terminal of the source follower transistor (SF) of the first pixel (PX1). The first floating diffusion interconnect line (FM1) may include a conductive material (e.g., a metal material).

A second floating diffusion interconnect line (FM2) may contact the second floating diffusion region (FD2). The second floating diffusion interconnect line (FM2) may connect (not shown) the second floating diffusion region (FD2) to a gate terminal of the source follower transistor (SF) of the second pixel (PX2). The second floating diffusion interconnect line (FM2) may include a conductive material (e.g., a metal material).

The semiconductor substrate 400 may include a first body region 411, a second body region 412, a first photoelectric conversion element (PD1), a second photoelectric conversion element (PD2), a pixel isolation structure (ISO), a first floating diffusion region (FD1), and a second floating diffusion region (FD2). The semiconductor substrate 400 may include a back surface 401 upon which incident light is incident, and a front surface 402 facing or opposite to the back surface 401.

The first photoelectric conversion element (PD1) may be a region including impurities of a first conductivity type (e.g., N-type). In one embodiment, the first photoelectric conversion element (PD1) may include a first upper photoelectric conversion region (SPD1) and a first lower photoelectric conversion region (DPD1) disposed under the first upper photoelectric conversion region (SPD1). Thus, in one implementation, the first upper photoelectric conversion region (SPD1) and the first lower photoelectric conversion region (DPD1) may be disposed along a vertical direction.

A depth of the first upper photoelectric conversion region (SPD1) from the front surface 402 of the semiconductor substrate 400 may be less than a depth of the first lower photoelectric conversion region (DPD1) from the front surface 402 of the semiconductor substrate 400. In the example as shown in FIG. 4A, a thickness of the first upper photoelectric conversion region (SPD1) that extends along a direction further away from the front surface 402 is less than the thickness of the first lower photoelectric conversion region (DPD1) that extends along the direction further away from the front surface 402. The first upper photoelectric conversion region (SPD1) may contact a top surface of the first lower photoelectric conversion region (DPD1). A width of the first upper photoelectric conversion region (SPD1) may be a first width (W1). The first upper photoelectric conversion region (SPD1) may be spaced apart from the first floating diffusion region (FD1) when viewed in a vertical direction.

A depth by which the first lower photoelectric conversion region (DPD1) is spaced apart from the front surface 402 of the semiconductor substrate 400 may be greater than that of the first upper photoelectric conversion region (SPD1). The first lower photoelectric conversion region (DPD1) may contact a bottom surface of the first upper photoelectric conversion region (SPD1). A width of the first lower photoelectric conversion region (DPD1) may be a second width (W2). The second width (W2) may be larger than the first width (W1). The first lower photoelectric conversion region (DPD1) may overlap the first floating diffusion region (FD1) when viewed in a vertical direction.

The second photoelectric conversion element (PD2) may be or include a region including impurities of the first conductive type. According to one embodiment, the second photoelectric conversion element (PD2) may include a second upper photoelectric conversion region (SPD2) and a second lower photoelectric conversion region (DPD2).

A depth by which the second upper photoelectric conversion region (SPD2) is spaced apart from the front surface 402 of the semiconductor substrate 400 may be smaller than that of the second lower photoelectric conversion region (DPD2). The second upper photoelectric conversion region (SPD2) may contact a top surface of the second lower photoelectric conversion region (DPD2). The second upper photoelectric conversion region (SPD2) may be spaced apart from the second floating diffusion region (FD2) when viewed in a vertical direction.

A depth by which the second lower photoelectric conversion region (DPD2) is spaced apart from the front surface 402 of the semiconductor substrate 400 may be greater than that of the second upper photoelectric conversion region (SPD2). The second lower photoelectric conversion region (DPD2) may contact the bottom surface of the second upper photoelectric conversion region (SPD2). The second lower photoelectric conversion region (DPD2) may overlap the second floating diffusion region (FD2) when viewed in a vertical direction.

The first body region 411 may include impurities of a second conductivity type (e.g., P type). The first body region 411 may be a region surrounding the first photoelectric conversion element (PD1). The first body region 411 may be disposed on sides of the first photoelectric conversion element (PD1).

The second body region 412 may include impurities of the second conductivity type. The second body region 412 may be a region surrounding the second photoelectric conversion element (PD2). The second body region 412 may be disposed on sides of the second photoelectric conversion element (PD2).

A pixel isolation structure (ISO) may be arranged at a boundary between adjacent pixels. The pixel isolation structure (ISO) may be, for example, an insulation region extending from the front surface 402 to the inside of the semiconductor substrate 400. The pixel isolation structure (ISO) may be, for another example, an insulation region extending from the back surface 401 into the semiconductor substrate 400. The pixel isolation structure (ISO) may include an insulation material (e.g., silicon oxide, silicon nitride, etc.) having insulation properties. The pixel isolation structure (ISO) may prevent optical crosstalk within the semiconductor substrate 400.

The first floating diffusion region (FD1) may include silicide. For example, the first floating diffusion region (FD1) may include a silicide region (e.g., a silicide layer) that is recessed into the semiconductor substrate 400.

In one embodiment, the first floating diffusion region (FD1) may include silicide only without including materials other than the silicide. In the example, the first floating diffusion region (FD1) may be implemented as the silicide region disposed in the semiconductor substrate 400. Each of the side surface and the bottom surface of the silicide region of the first floating diffusion region (FD1) may be formed to contact the first body region 411. The silicide region may be arranged or disposed along the top surface, the side surface, and the bottom surface of the first floating diffusion region (FD1). In the example, the silicide region may extend to the interior of the first floating diffusion region (FD1). The silicide may gap-fill the interior of the first floating diffusion region (FD1).

When the first floating diffusion region (FD1) is formed as a doped semiconductor region, the first floating diffusion region (FD1) should be arranged to overlap the first gate electrode layer (TXE1) when viewed in the vertical direction. As a result, a channel through which photocharges generated by the first photoelectric conversion element (PD1) move to the first floating diffusion region (FD1) when a high-level transfer signal is applied to the first gate electrode layer (TXE1) can be easily formed. However, when the first floating diffusion region (FD1) and the first gate electrode layer (TXE1) overlap each other, parasitic capacitance between the gate and the drain may be formed, which results undesirable increase in capacitance, and there may occur a problem in which the conversion gain (CG) of the source follower transistor (SF) decreases.

Silicide is an alloy formed by a chemical reaction between metal and silicon. When the first floating diffusion region (FD1) is formed of or includes silicide, contact resistance with the first floating diffusion interconnect line (FM1) may be significantly reduced. In addition, as compared to the case that the first floating diffusion region (FD1) is implemented as a doped semiconductor region, if the first floating diffusion region (FD1) is formed of or includes silicide, when the first transfer gate (TXG1) is turned on (i.e., ON state), conductivity between the first photoelectric conversion element (PD1) and the first floating diffusion region (FD1) may be further improved, and the operating speed may also become faster. In some embodiments, since the first floating diffusion region (FD1) is formed of or includes silicide, even if the first floating diffusion region (FD1) is spaced apart from the first gate electrode layer (TXE1) without overlapping the first gate electrode layer (TXE1) in the vertical direction, the size of the first photoelectric conversion element (PD1) increases and the distance between the first floating diffusion region (FD1) and the first photoelectric conversion element (PD1) decreases, so that a time required for photocharges to move from the first photoelectric conversion element (PD1) to the first floating diffusion region (FD1) can be reduced.

If the first floating diffusion region (FD1) is formed of or includes silicide and the first transfer gate (TXG1) and the first floating diffusion region (FD1) are spaced apart from each other when viewed in the vertical direction, gate-drain parasitic capacitance between the first transfer gate (TXG1) and the first floating diffusion region (FD1) is not formed, so that capacitance of the first transfer transistor (TX1) can be reduced and a conversion gain can be increased. In addition, the first width (W1) of the first upper photoelectric conversion region (SPD1) of the first photoelectric conversion elements (PD1) may be formed relatively wider, so that a full well capacity of the first photoelectric conversion elements (PD1) can be increased.

As the first floating diffusion region (FD1) is formed of or include a silicide, a potential between the drain and the channel decreases when the channel is formed, and a current can flow relatively more easily, so that the electric field distribution can be alleviated and the probability of occurrence of reverse tunneling can be reduced, thereby reducing the probability of occurrence of the GIDL phenomenon. When the GIDL phenomenon is reduced and leakage from the first floating diffusion region (FD1) is reduced, the operation of the first pixel (PX1) can be improved.

As the first floating diffusion region (FD1) is formed of or include a silicide, contact resistance with the first floating diffusion interconnect line (FM1) connected to the gate of the source follower transistor (SF) corresponding to the first pixel (PX1) can be reduced, so that noise can be reduced.

Various effects, which are obtained by forming the first floating diffusion region (FD1) to include silicide, can also be expected from the second floating diffusion region (FD2) including silicide.

In the following description of the second floating diffusion region (FD2), the same descriptions as those described for the first floating diffusion region (FD1) will herein be omitted.

The second floating diffusion region (FD2) may include a silicide. For example, the second floating diffusion region (FD2) may include a silicide region (e.g., a silicide layer) that is recessed into the interior of the semiconductor substrate 400.

In one embodiment, the second floating diffusion region (FD2) may include silicide only without including other materials than silicide. In the example, the second floating diffusion region (FD2) may be implemented as the silicide region disposed in the semiconductor substrate 400. Each of the side surface and the bottom surface of the silicide region of the second floating diffusion region (FD2) may contact the second body region 412. The silicide region may be arranged or disposed along the top surface, the side surface, and the bottom surface of the second floating diffusion region (FD2). The silicide region may extend into the second floating diffusion region (FD2). The silicide may gap-fill the interior of the second floating diffusion region (FD2).

When the second floating diffusion region (FD2) is formed of a silicide, contact resistance with the second floating diffusion interconnect line (FM2) may be significantly reduced. In addition, the second floating diffusion region (FD2) may be spaced apart from the second gate electrode layer (TXE2) when viewed in the vertical direction. As the second floating diffusion region (FD2) is formed of or includes a silicide, contact resistance with the second floating diffusion interconnect line (FM2) connected to the gate of the source follower transistor (SF) corresponding to the second pixel (PX2) may be reduced, thereby reducing noise.

Various effects, which result from forming the first floating diffusion region (FD1) to include silicide, can also be obtained by the second floating diffusion region (FD2) including silicide.

A grid region (GRD) can be arranged on the back surface 401 of the semiconductor substrate 400. The grid region (GRD) may be arranged between adjacent pixels. For example, the grid region (GRD) may be arranged between the first pixel (PX1) and the second pixel (PX2).

The grid region (GRD) may prevent optical crosstalk. For example, optical crosstalk may be prevented by reflecting or absorbing incident light that is first obliquely incident upon the first pixel (PX1) and then incident upon the second pixel (PX2) adjacent to the first pixel (PX1).

The grid region (GRD) may include a metal material having a high light absorption rate (for example, tungsten W). The grid region (GRD) may also include a material with high light reflectivity (e.g., air). A first color filter (CF1) may be disposed in the first pixel (PX1) and configured to selectively transmit incident light according to a wavelength range. For example, the first color filter (CF1) may selectively transmit light in a first wavelength range (e.g., 400 nm to 500 nm). The first color filter (CF1) may be disposed between grid structures (GRDs) within the first pixel (PX1).

The second color filter (CF2) may be disposed in the second pixel (PX2) and configured to selectively transmit incident light according to a wavelength range. In one embodiment, the second color filter (CF2) may selectively transmit light in the first wavelength range. In another embodiment, the second color filter (CF2) may selectively transmit light in a second wavelength range (e.g., 500 nm to 600 nm). The second color filter (CF2) may be disposed between grid structures (GRDs) within the second pixel (PX2).

The first microlens (ML1) may refract incident light, and may focus the refracted light onto the first color filter (CF1). The first microlens (ML1) may be disposed within the first pixel (PX1).

The second microlens (ML2) may refract incident light, and may focus the refracted light onto the second color filter (CF2). The second microlens (ML2) may be disposed within the second pixel (PX2).

FIG. 4B is a cross-sectional view 42 illustrating an example of the pixel array 130 taken along the line A-A′ shown in FIG. 2 according to a second embodiment of the present disclosure.

Referring to FIGS. 2, 3B, and 4B, the second cross-sectional view 42 according to the second embodiment may be a cross-sectional view for an embodiment in which the first to fourth pixels (PX1~PX4) share one floating diffusion region (FD).

The second cross-sectional view 42 may include a first transfer gate (TXG1), a first transfer interconnect line (TM1), a second transfer gate (TXG2), a second transfer interconnect line (TM2), a floating diffusion interconnect line (FM), a semiconductor substrate 400, a grid structure (GRD), a first color filter (CF1), a second color filter (CF2), a first microlens (ML1), and a second microlens (ML2).

In the following description of FIG. 4B, the same descriptions as those described with regard to FIG. 4A will herein be omitted.

A floating diffusion interconnect line (FM) may connect a gate of a source follower transistor corresponding to a pixel group (PG) including the floating diffusion region (FD) and the first to fourth pixels (PX1~PX4).

The semiconductor substrate 400 may include a first photoelectric conversion element (PD1), a second photoelectric conversion element (PD2), a first body region 411, a second body region 412, a pixel isolation structure (ISO), and a floating diffusion region (FD).

The first photoelectric conversion element (PD1) may include a first upper photoelectric conversion region (SPD1) and a first lower photoelectric conversion region (DPD1). The second photoelectric conversion element (PD2) may include a second upper photoelectric conversion region (SPD2) and a second lower photoelectric conversion region (DPD2).

The first upper photoelectric conversion region (SPD1) may have a third width (W3). The first lower photoelectric conversion region (DPD1) may have a fourth width (W4). The fourth width (W4) may be larger than the third width (W3).

The floating diffusion region (FD) may be arranged at the center of the pixel group (PG). The floating diffusion region (FD) may be disposed around a boundary between the first pixel (PX1) and the second pixel (PX2). The floating diffusion region (FD) may include silicide. The floating diffusion region (FD) may be disposed between a first transfer gate (TXG1) and a second transfer gate (TXG2). The floating diffusion region (FD) may be or include a drain region shared by the first transfer transistor (TX1) and the second transfer transistor (TX2). The floating diffusion region (FD) may extend in a horizontal direction, and may overlap each of the first lower photoelectric conversion region (DPD1) and the second lower photoelectric conversion region (DPD2).

A first body region 411 may surround the first photoelectric conversion element (PD1). The first body region 411 may be disposed on sides of the first photoelectric conversion element (PD1). The second body region 412 may surround the second photoelectric conversion element (PD2). The second body region 412 may be disposed on sides of the second photoelectric conversion element (PD2). The first body region 411 and the second body region 412 may be formed to contact each other.

The pixel isolation structure (ISO) may not be disposed on at least a portion of a boundary between the first pixel (PX1) and the second pixel (PX2).

The first transfer gate (TXG1) may include a first gate electrode layer (TXE1) and a first gate spacer (TXS1). The first gate electrode layer (TXE1) may include a first silicide region (SC1).

The first silicide region (SC1) may mean a portion where silicide is formed on at least a portion of the upper portion of the first gate electrode layer (TXE1) in a process of forming a silicide region (e.g., silicide layer) in the floating diffusion region (FD). A cross-sectional area (or volume) occupied by the first silicide region (SC1) may vary depending on a mask pattern for forming the silicide region of the floating diffusion region (FD). The first silicide region (SC1) may be located adjacent to the first gate spacer (TXS1) which is relatively close to the floating diffusion region (FD).

The second transfer gate (TXG2) may include a second gate electrode layer (TXE2) and a second gate spacer (TXS2). The second silicide region (SC2) may mean a portion where silicide is formed on at least a portion of the upper portion of the second gate electrode layer (TXE2) in a process of forming a silicide region (e.g., silicide layer) in the floating diffusion region (FD). A cross-sectional area (or volume) occupied by the second silicide region (SC2) may vary depending on a mask pattern for forming a silicide region in the second floating diffusion region (FD2). The second silicide region (SC2) may be located adjacent to the second gate spacer (TXS2) that is relatively close to the floating diffusion region (FD).

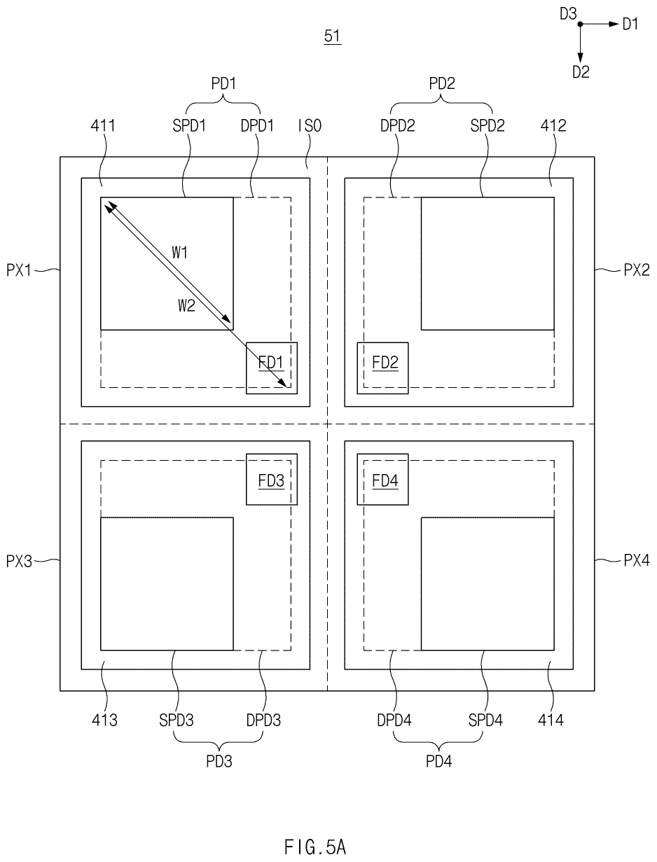

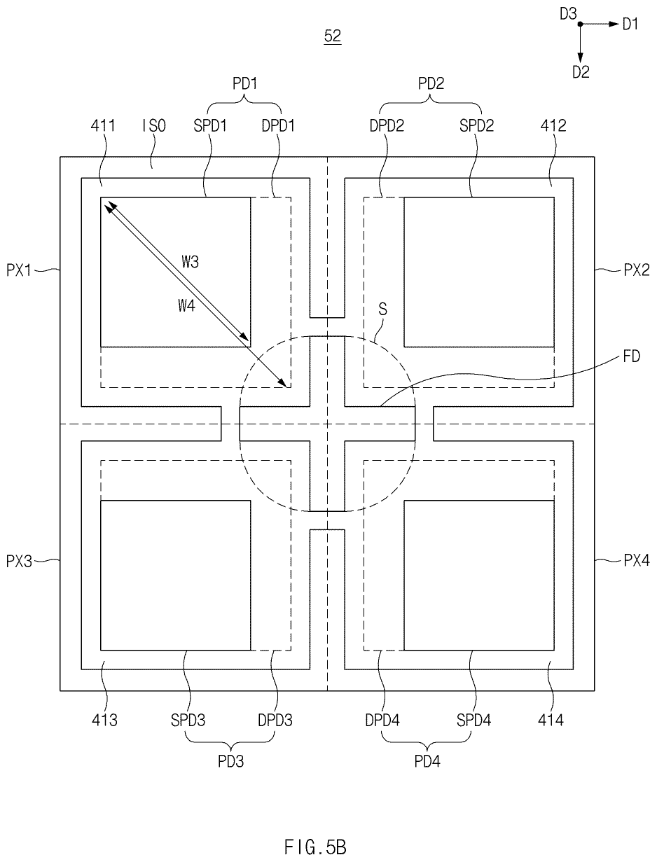

FIG. 5A is a plan view 51 illustrating an example of the first to fourth pixels (PX1~PX4) shown in FIG. 2 according to the first embodiment of the present disclosure.

Referring to FIGS. 2, 3A, 4A, and 5A, the first plan view 51 may include a pixel isolation structure (ISO), first to fourth photoelectric conversion elements (PD1~PD4), first to fourth body regions (411~414), and first to fourth floating diffusion regions (FD1~FD4).

The pixel isolation structure (ISO) may be arranged along a boundary of each of the first to fourth pixels (PX1~PX4). For example, the pixel isolation structure (ISO) may be arranged along a boundary between the first pixel (PX1) and the second pixel (PX2). The pixel isolation structure (ISO) may be arranged along a boundary between the second pixel (PX2) and the fourth pixel (PX4). The pixel isolation structure (ISO) may be arranged along a boundary between the third pixel (PX3) and the fourth pixel (PX4). The pixel isolation structure (ISO) may be arranged along a boundary between the first pixel (PX1) and the third pixel (PX3).

The first photoelectric conversion element (PD1) may include a first upper photoelectric conversion region (SPD1) and a first lower photoelectric conversion region (DPD1). The first width (W1) of the first upper photoelectric conversion region (SPD1) may be less than the second width (W2) of the first lower photoelectric conversion region (DPD1). The first upper photoelectric conversion region (SPD1) may be spaced apart from the first floating diffusion region (FD1). The first lower photoelectric conversion region (DPD1) may overlap the first floating diffusion region (FD1).

The first body region 411 may surround the first photoelectric conversion element (PD1).

The second photoelectric conversion element (PD2) may be spaced apart from the first photoelectric conversion element (PD1) in a first direction (D1). The second photoelectric conversion element (PD2) may include a second upper photoelectric conversion region (SPD2) and a second lower photoelectric conversion region (DPD2). The second upper photoelectric conversion region (SPD2) may be spaced apart from the second floating diffusion region (FD2). The second lower photoelectric conversion region (DPD2) may overlap the second floating diffusion region (FD2). A width (e.g., a width in a diagonal direction) of the second upper photoelectric conversion region (SPD2) may be less than a width of the second lower photoelectric conversion region (DPD2).

The second body region 412 may surround the second photoelectric conversion element (PD2).

The third photoelectric conversion element (PD3) may be spaced apart from the first photoelectric conversion element (PD1) in a second direction (D2). The third photoelectric conversion element (PD3) may include a third upper photoelectric conversion region (SPD3) and a third lower photoelectric conversion region (DPD3). The third upper photoelectric conversion region (SPD3) may be spaced apart from the third floating diffusion region (FD3). The third lower photoelectric conversion region (DPD3) may overlap the third floating diffusion region (FD3). A width (e.g., a width in a diagonal direction) of the third upper photoelectric conversion region (SPD3) may be less than a width of the third lower photoelectric conversion region (DPD3). The third photoelectric conversion element (PD3) may include impurities of the first conductivity type.

The third body region 413 may surround the third photoelectric conversion element (PD3). The third body region 413 may include impurities of the second conductivity type.

The fourth photoelectric conversion element (PD4) may be spaced apart from the third photoelectric conversion element (PD3) in the first direction (D1). The fourth photoelectric conversion element (PD4) may be spaced apart from the second photoelectric conversion element (PD2) in the second direction (D2). The fourth photoelectric conversion element (PD4) may include a fourth upper photoelectric conversion region (SPD4) and a fourth lower photoelectric conversion region (DPD4). The fourth upper photoelectric conversion region (SPD4) may be spaced apart from the fourth floating diffusion region (FD4). The fourth lower photoelectric conversion region (DPD4) may overlap the fourth floating diffusion region (FD4). A width (e.g., a width in the diagonal direction) of the fourth upper photoelectric conversion region (SPD4) may be less than a width of the fourth lower photoelectric conversion region (DPD4). The fourth photoelectric conversion element (PD4) may include impurities of the first conductivity type.

The fourth body region 414 may surround the fourth photoelectric conversion element (PD4). The fourth body region 414 may include impurities of the second conductivity type.

As the first to fourth pixels (PX1~PX4) are arranged in a (2×2) matrix structure, the first to fourth photoelectric conversion elements (PD1~PD4) may also be arranged in a (2×2) matrix structure.

FIG. 5B is a plan view 52 illustrating an example of the first to fourth pixels (PX1~PX4) shown in FIG. 2 according to the second embodiment of the present disclosure.

Referring to FIGS. 2, 3B, 4B, and 5B, the second plan view 52 may include a pixel isolation structure (ISO), first to fourth photoelectric conversion elements (PD1~PD4), first to fourth body regions (411~414), and a floating diffusion region (FD).

In the following description of FIG. 5B, the same as those described with reference to FIG. 5A will herein be omitted.

The pixel isolation structure (ISO) may be arranged along a boundary of each of the first to fourth pixels (PX1~PX4). For example, the pixel isolation structure (ISO) may be arranged along a boundary between the first pixel (PX1) and the second pixel (PX2). The pixel isolation structure (ISO) may be arranged at a boundary between the second pixel (PX2) and the fourth pixel (PX4). The pixel isolation structure (ISO) may be arranged at a boundary between the third pixel (PX3) and the fourth pixel (PX4). The pixel isolation structure (ISO) may be arranged at a boundary between the first pixel (PX1) and the third pixel (PX3). The pixel isolation structure (ISO) may be spaced apart from the floating diffusion region (FD). The pixel isolation structure (ISO) may be arranged along a boundary of the pixel group (PG).

The floating diffusion region (FD) may be shared by the first to fourth pixels (PX1~PX4). The floating diffusion region (FD) may be arranged at the center of the pixel group (PG). In the example as shown in FIG. 5B, the floating diffusion region (FD) may be arranged between any two photoelectric conversion elements. For example, the floating diffusion region (FD) may be arranged between the first photoelectric conversion element (PD1) and the fourth photoelectric conversion element (PD4). The floating diffusion region (FD) may be arranged between the second photoelectric conversion element (PD2) and the third photoelectric conversion element (PD3). The floating diffusion region (FD) may have a first portion extending from the center of the pixel group (PG) in the first direction (D1). The floating diffusion region (FD) may have a second portion extending from the center of the pixel group (PG) in the opposite direction to the first direction (D1). The floating diffusion region (FD) may have a third portion extending from the center of the pixel group (PG) in the second direction (D2). The floating diffusion region (FD) may have a fourth portion extending from the center of the pixel group (PG) in the opposite direction to the second direction (D2). For example, the floating diffusion region (FD) may have a cross shape having the first to fourth portions extending in different directions from one another. The floating diffusion region (FD) may be spaced apart from the first to fourth upper photoelectric conversion regions (SPD1~SPD4). Since the floating diffusion region (FD) has a cross shape, the width of each of the first to fourth upper photoelectric conversion regions (SPD1~SPD4) in the diagonal direction may further increase, and the full well capacity of each of the first to fourth photoelectric conversion elements (PD1~PD4) may increase.

The first photoelectric conversion element (PD1) may include a first upper photoelectric conversion region (SPD1) and a first lower photoelectric conversion region (DPD1). The width of the first upper photoelectric conversion region (SPD1) in the diagonal direction may be a third width (W3). The width of the first lower photoelectric conversion region (DPD1) in the diagonal direction may be a fourth width (W4).

Although the widths of the second to fourth upper photoelectric conversion regions (SPD2~SPD4) in the diagonal direction and the widths of the second to fourth lower photoelectric conversion regions (DPD2~DPD4) in the diagonal direction are not illustrated to prevent overcrowding of the drawings, the width of each of the second to fourth upper photoelectric conversion regions (SPD2~SPD4) in the diagonal direction may be equal to the third width (W3). The width of each of the second to fourth lower photoelectric conversion regions (DPD2~DPD4) in the diagonal direction may be equal to the fourth width (W4).

The second photoelectric conversion element (PD2) may include a second upper photoelectric conversion region (SPD2) and a second lower photoelectric conversion region (DPD2). The third photoelectric conversion element (PD3) may include a third upper photoelectric conversion region (SPD3) and a third lower photoelectric conversion region (DPD3). The fourth photoelectric conversion element (PD4) may include a fourth upper photoelectric conversion region (SPD4) and a fourth lower photoelectric conversion region (DPD4).

Although the widths of the second to fourth upper photoelectric conversion regions (SPD2~SPD4) in the diagonal direction and the widths of the second to fourth lower photoelectric conversion regions (DPD2~DPD4) in the diagonal direction are not illustrated to prevent overcrowding of the drawings, the width of each of the second to fourth upper photoelectric conversion regions (SPD2~SPD4) in the diagonal direction may be equal to the fifth width (W5). The width of each of the second to fourth lower photoelectric conversion regions (DPD2~DPD4) in the diagonal direction may be equal to the fourth width (W4).

A silicide formation region (S) may mean a mask pattern for forming a silicide region (e.g., a silicide layer) in a process for forming the silicide region in the floating diffusion region (FD).

In FIG. 5B, illustration of the transfer gate is omitted to prevent overcrowding of the drawings, but the first silicide region (SC1) of FIG. 4B may be formed in a portion where the first gate electrode layer TXE1 (see FIG. 4B) and the silicide formation region (S) overlap each other. In addition, the second silicide region (SC2) of FIG. 4B may be formed in a portion where the second gate electrode layer TXE2 (see FIG. 4B) and the silicide formation region (S) overlap each other.

Each of the first and second embodiments relates to the floating diffusion regions (FD or FD1~FD4) including silicide. As each of the floating diffusion regions (FD or FD1~FD4) is formed of or includes silicide, contact resistance with the floating diffusion interconnect line can be reduced. In addition, since conductivity between the photoelectric conversion element and the floating diffusion region is improved, the gate electrode layer of the transfer gate and the floating diffusion region do not need to overlap each other in the vertical direction, so that unnecessary parasitic capacitance between the gate and the drain can be reduced.

In addition, the embodiments of the present disclosure in which the floating diffusion region is formed of or includes silicide can enable the photoelectric conversion element to have a larger size, thereby providing a pixel with increased full well capacitance. In addition, since leakage of the floating diffusion region is reduced, the operating characteristics of the pixel can be improved, and since contact resistance with the floating diffusion interconnect line is reduced, noise of the pixel signal can be reduced.

As is apparent from the above description, the embodiments of the present disclosure may provide the image sensing device that prevents a reduction in conversion gain by minimizing the amount of unnecessary capacitance because a floating diffusion region and a transfer transistor does not overlap each other, so that occurrence of gate induced drain leakage (GIDL) can be prevented.

The embodiments of the present disclosure may provide a variety of effects capable of being directly or indirectly recognized through the above-mentioned patent document.

Those skilled in the art will appreciate that the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in this patent document.

What is claimed is:

1. An image sensing device, comprising:
a semiconductor substrate;
a photoelectric conversion element disposed in the semiconductor substrate, and configured to generate photocharges in response to incident light;
a body region formed in the semiconductor substrate and configured to surround the photoelectric conversion element; and
a floating diffusion region formed in the semiconductor substrate adjacent to the photoelectric conversion element to receive and store the photocharges generated by the photoelectric conversion element, the floating diffusion region structured to include a silicide region that is recessed into the semiconductor substrate and includes a side surface and a bottom surface that are in contact with the body region.

2. The image sensing device according to claim 1, further comprising:
a transfer gate disposed on a surface of the semiconductor substrate, and configured to overlap the photoelectric conversion element in a vertical direction perpendicular to the surface of the semiconductor substrate,
wherein
a gate electrode layer of the transfer gate is spaced apart from the floating diffusion region in the vertical direction.

3. The image sensing device according to claim 2, wherein:
at least a portion of an upper portion of the gate electrode layer includes a silicide.

4. The image sensing device according to claim 2, wherein the photoelectric conversion element includes:
an upper photoelectric conversion region configured to have a first width; and
a lower photoelectric conversion region formed at a location below the upper photoelectric conversion region and configured to have a second width greater than the first width.

5. The image sensing device according to claim 4, wherein:
the upper photoelectric conversion region is spaced apart from the floating diffusion region; and
the lower photoelectric conversion region is formed to overlap the floating diffusion region.

6. The image sensing device according to claim 1, wherein:
the photoelectric conversion element includes impurities of a first conductivity type; and
the body region includes impurities of a second conductivity type opposite to the first conductivity type.

7. The image sensing device according to claim 1, wherein:
the silicide region is disposed along a top surface, a side surface, and a bottom surface of the floating diffusion region.

8. The image sensing device according to claim 7, wherein:
the silicide region extends into the floating diffusion region.

9. The image sensing device according to claim 7, wherein:
the silicide region gap-fills an interior of the floating diffusion region.

10. An image sensing device, comprising:
first to fourth photoelectric conversion elements disposed in a semiconductor substrate to be spaced apart from each other, each of the first to fourth photoelectric conversion elements configured to generate photocharges in response to incident light;
a body region surrounding each of the first to fourth photoelectric conversion elements; and
a floating diffusion region including a silicide region recessed into the semiconductor substrate and configured to store photocharges generated by the first photoelectric conversion element,
wherein
the silicide region is arranged along a top surface, a side surface, and a bottom surface of the floating diffusion region.

11. The image sensing device according to claim 10, further comprising:
a transfer gate configured to move the photocharges generated by the first photoelectric conversion element to the floating diffusion region,
wherein
a gate electrode layer of the transfer gate is spaced apart from the floating diffusion region in a vertical direction perpendicular to one surface of the semiconductor substrate.

12. The image sensing device according to claim 11, wherein:
at least a portion of an upper portion of the gate electrode layer includes a silicide.

13. The image sensing device according to claim 10, wherein:
the first photoelectric conversion element and the second photoelectric conversion element are spaced apart from each other in a first direction, the first photoelectric conversion element and the third photoelectric conversion element are spaced apart from each other in a second direction; and
the floating diffusion region is arranged between the second photoelectric conversion element and the third photoelectric conversion element.

14. The image sensing device according to claim 13, wherein:
the floating diffusion region extends between the first and second photoelectric conversion elements in the second direction; and
the floating diffusion region extends between the first and third photoelectric conversion elements in the first direction.

15. The image sensing device according to claim 10, wherein:
the silicide region extends into the floating diffusion region.

16. The image sensing device according to claim 10, wherein:
the silicide region gap-fills an interior of the floating diffusion region.

17. The image sensing device according to claim 10, wherein:
each of the first to fourth photoelectric conversion elements includes impurities of a first conductivity type; and
the body region includes impurities of a second conductivity type opposite to the first conductivity type.

18. The image sensing device according to claim 10, wherein:
the floating diffusion region is shared by the first to fourth photoelectric conversion elements to receive photocharges each of the first to fourth photoelectric conversion elements.
